(19) United States
(12) Patent Application Publication
(10) Pub. No.: US 2012/0044132 A1
(43) Pub. Date: Feb. 23, 2012

(54) SHIFT REGISTER, SCANNING LINE DRIVE CIRCUIT, ELECTRO-OPTICAL DEVICE, AND ELECTRONIC APPARATUS

(75) Inventors: Masayuki Koga, Tottori (JP); Yukiya Hirabayashi, Tottori (JP)

(73) Assignee: SONY CORPORATION, Tokyo (JP)

(21) Appl. No.: 13/030,409

(22) Filed: Feb. 18, 2011

(30) Foreign Application Priority Data
Feb. 26, 2010 (JP) P2010-041673

(51) Int. Cl. G09G 3/36; G09G 5/00; G11C 19/00

(52) U.S. Cl. 345/100; 377/64

(57) ABSTRACT

Disclosed herein is a shift register including shift register unit circuits of a plurality of stages. Each of the shift register unit circuits of the plurality of stages includes a first transistor having a source and a drain to one of which a first clock signal is input and a gate to which a second clock signal obtained by substantially inverting the first clock signal is input. When the second clock signal at one of an H level and an L level is input to the gate of the first transistor, the first clock signal at the other of the H level and the L level is input to one of the source and the drain of the first transistor.

### CROSS REFERENCES TO RELATED APPLICATIONS

The present application claims priority to Japanese Priority Patent Application JP 2010-041673 filed in the Japan Patent Office on Feb. 26, 2010, the entire content of which is hereby incorporated by reference.

### BACKGROUND

The present application relates to shift registers, scanning line drive circuits, electro-optical devices, and electronic apparatus, and particularly to a shift register, a scanning line drive circuit, an electro-optical device, and electronic apparatus each having a transistor.

As the related art, shift registers, scanning line drive circuits, electro-optical devices, and electronic apparatus each having a transistor are known (refer to e.g. Japanese Patent Laid-open No. Hei 7-182891 and Japanese Patent Laid-open No. 2006-351171 (hereinafter, Patent Documents 1 and 2)).

Patent Documents 1 and 2 each disclose a shift register including a transistor that has the source and drain one of which is fixed at an L-level potential and is switched between the on-state and the off-state by alternate input of an H-level signal and an L-level signal to its gate.

### SUMMARY

However, in the shift registers described in Patent Documents 1 and 2, the signal of the same potential as that of the signal input to one of the source and drain of the transistor (L-level signal) or the H-level signal is input to the gate of the transistor. If the H-level signal is input to the gate of the transistor, a charge is drawn toward the gate side and accumulated on the gate insulating film side. Thus, the threshold voltage of the transistor is shifted toward the H-level-side potential, which causes an inconvenience that the transistor does not enter the on-state although the H-level signal is input to its gate. This results in a problem that the life of the shift register is shortened attributed to the deterioration of the transistor due to this variation in the threshold voltage.

There is a desire for the present application to provide a shift register, a scanning line drive circuit, an electro-optical device, and electronic apparatus that are allowed to have a longer life through suppression of the deterioration of a transistor.

According to a first embodiment, there is provided a shift register including shift register unit circuits of a plurality of stages. Each of the shift register unit circuits of the plurality of stages includes a first transistor having a source and a drain to one of which a first clock signal is input and a gate to which a second clock signal obtained by substantially inverting the first clock signal is input. When the second clock signal at one of an H level and an L level is input to the gate of the first transistor, the first clock signal at the other of the H level and the L level is input to one of the source and the drain of the first transistor.

In the shift register according to the first embodiment, as described above, when the second clock signal at one of the H level and the L level is input to the gate of the first transistor, the first clock signal at the other of the H level and the L level is input to one of the source and the drain of the first transistor. Due to this feature, when the H-level signal is input to the gate of the first transistor and the L-level signal is input to one of the source and the drain of the first transistor, the voltage of the gate of the first transistor becomes higher than the voltage of its channel (voltage between the source and the drain). Thus, a charge is drawn toward the gate side of the first transistor and accumulated on the gate insulating film side. On the other hand, when the L-level signal is input to the gate of the first transistor and the H-level signal is input to one of the source and the drain of the first transistor, the voltage of the channel of the first transistor (voltage between the source and the drain) becomes higher than the voltage of its gate. Thus, the charge accumulated on the gate insulating film side of the first transistor is moved from the gate insulating film side to the source or drain side. This allows a charge to be less readily accumulated on the gate insulating film side of the first transistor and thus can suppress the shift of the threshold voltage of the first transistor attributed to the accumulation of a charge on the gate insulating film side. As a result, the deterioration of the first transistor is suppressed, which can extend the life of the shift register.

In the shift register according to the first embodiment, it is preferable that one of the first clock signal and the second clock signal become the H level from the L level after passage of a period during which both of the first clock signal input to one of the source and the drain of the first transistor and the second clock signal input to the gate of the first transistor are at the L level. If such a configuration is employed, one of the first clock signal and the second clock signal becomes the H level from the L level after the first transistor is surely set to the off-state. This can suppress outputting of the H-level signal before the setting of the first transistor to the off-state.

In the shift register according to the first embodiment, it is preferable to employ the following configuration. Specifically, each of the shift register unit circuits of the plurality of stages includes a second transistor having a source and a drain to one of which the first clock signal is input. Furthermore, the other of the source and the drain of the second transistor is connected to the other of the source and the drain of the first transistor and forms an output terminal of the shift register unit circuit. In addition, the output terminal of the shift register unit circuit is connected to an input terminal of the next stage of the shift register unit circuit. Employing such a configuration allows a charge to be less readily accumulated on the gate insulating film side of the first and second transistors, and thus can suppress the shift of the threshold voltage of the first and second transistors attributed to the accumulation of a charge on the gate insulating films side. Thereby, the signal can be surely output to the scanning line.

In this case, it is preferable to employ the following configuration. Specifically, each of the shift register unit circuits of the plurality of stages includes a capacitor having one electrode to which the same signal as a signal input to one of the source and the drain of the first transistor is input, and a third transistor having a gate connected to the other electrode of the capacitor. Furthermore, a signal at the L level is input to one of a source and a drain of the third transistor when a signal at the H level is input to the gate of the third transistor via the capacitor, and a signal at the H level is input to one of the source and the drain of the third transistor when a signal at the L level is input to the gate of the third transistor via the capacitor. Employing such a configuration allows a charge to be less readily accumulated on the gate insulating film side of the third transistor in addition to the gate insulating film side of the first and second transistors, and thus can suppress the shift of the threshold voltage of the third transistor attributed to the accumulation of a charge on the gate insulating film side. Consequently, the shift of the threshold voltage of the first, second, and third transistors can be suppressed.

In the shift register including the above-described third transistor, it is preferable that the same signal as a signal input to the gate of the first transistor be input to one of the source and the drain of the third transistor, and the same signal as the signal input to one of the source and the drain of the first transistor be input to the gate of the third transistor via the capacitor. If such a configuration is employed, the signal for suppressing the shift of the threshold voltage of the third transistor does not need to be additionally prepared, which can suppress increase in the degree of complexity of the circuit configuration.

In the shift register including the above-described second transistor, it is preferable that the first and second transistors each have an active layer formed of amorphous silicon. Employing such a configuration can suppress the deterioration of the performance of the transistors having the active layer formed of amorphous silicon, which is susceptible to performance deterioration, and thus can extend the life of the shift register.

In the shift register including the above-described second transistor, it is preferable that the first and second transistors be transistors of the same conductivity type. Employing such a configuration can suppress the deterioration of the performance of the transistors of the same conductivity type, and thus can extend the life of the shift register.

According to a second embodiment, there is provided a scanning line drive circuit that is provided together with a plurality of scanning lines, a plurality of data lines, and switching elements provided corresponding to the intersections of the scanning lines and the data lines, and is connected to the scanning lines. The scanning line drive circuit includes the shift register having the above-described configuration. The output terminal of the shift register unit circuit is connected to the scanning line. Employing such a configuration can obtain a scanning line drive circuit including a shift register allowed to have a longer life through suppression of the deterioration of the transistor.

According to a third embodiment, there is provided an electro-optical device including the scanning line drive circuit having the above-described configuration. Employing such a configuration can obtain an electro-optical device including a scanning line drive circuit allowed to have a longer life through suppression of the deterioration of the transistor.

According to a fourth embodiment, there is provided electronic apparatus including the electro-optical device having the above-described configuration. Employing such a configuration can obtain electronic apparatus including an electro-optical device allowed to have a longer life through suppression of the deterioration of the transistor.

Additional features and advantages are described herein, and will be apparent from the following Detailed Description and the figures.

### BRIEF DESCRIPTION OF THE FIGURES

FIG. 1 is a plan view of a liquid crystal display device according to a first embodiment;

FIG. 2 is a block diagram of a scanning line drive circuit according to the first embodiment;

FIG. 3 is an equivalent circuit diagram of a shift register unit circuit in the scanning line drive circuit according to the first embodiment;

FIG. 4 is a timing chart for explaining the operation of the scanning line drive circuit according to the first embodiment;

FIG. 5 is an equivalent circuit diagram of a shift register unit circuit in a scanning line drive circuit according to a second embodiment;

FIG. 6 is an equivalent circuit diagram of a shift register unit circuit in a scanning line drive circuit according to a third embodiment;

FIG. 7 is a diagram for explaining a first example of electronic apparatus employing any of the liquid crystal display devices according to the first to third embodiments of the present application;

FIG. 8 is a diagram for explaining a second example of the electronic apparatus employing any of the liquid crystal display devices according to the first to third embodiments of the present application; and

FIG. 9 is a diagram for explaining a third example of the electronic apparatus employing any of the liquid crystal display devices according to the first to third embodiments of the present application.

### DETAILED DESCRIPTION

Embodiments of the present application will be described below in detail with reference to the drawings.

### First Embodiment

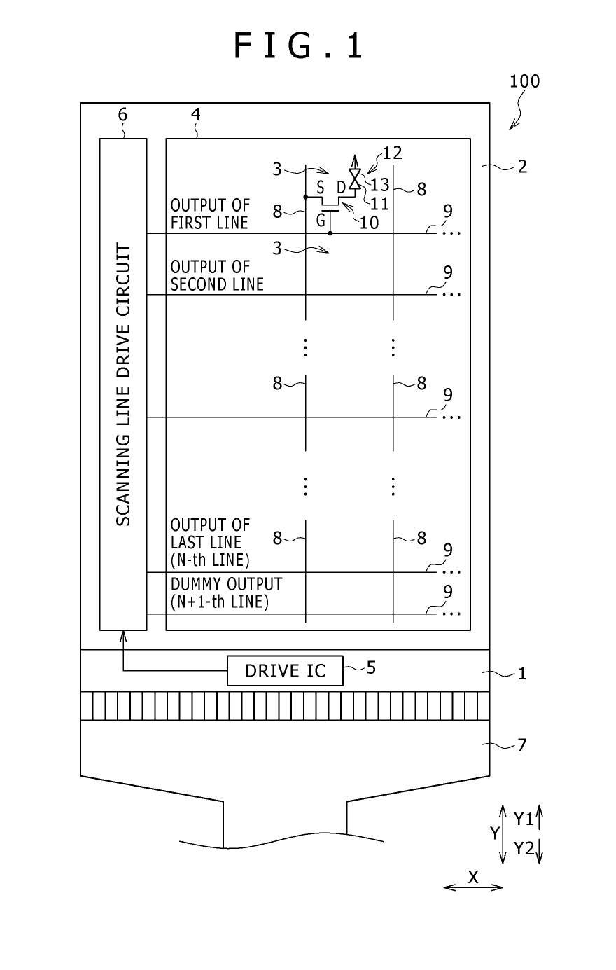

With reference to FIGS. 1 to 4, the configuration of a liquid crystal display device 100 according to a first embodiment will be described below. The description of the first embodiment relates to an example in which a scanning line drive circuit 6 of the present application is applied to the liquid crystal display device 100. The liquid crystal display device 100 is one example of the “electro-optical device” of the present application.

As shown in FIG. 1, the liquid crystal display device 100 of the first embodiment includes a TFT substrate 1 and a counter substrate 2 that are so disposed as to be opposed to each other, a display unit 4 including plural pixels 3, a drive IC (Integrated Circuit) 5 for driving the liquid crystal display device 100, a scanning line drive circuit 6 provided on the surface of the TFT substrate 1, and a flexible printed circuit (FPC) 7 to output various signals to the drive IC 5.

The display unit 4 includes plural data lines 8 extended along the Y-direction and plural scanning lines 9 that are so provided as to be substantially perpendicular to the data lines 8 and extended along the X-direction. The plural scanning lines 9 are connected to the scanning line drive circuit 6. The plural scanning lines 9 are juxtaposed in the Y-direction of the TFT substrate 1 and arranged in the order of the first line, the second line, the N-th line, and the (N+1)-th line in the direction from the Y1-direction side toward the Y2-direction side.

The pixel 3 is provided in the area at the intersection of the scanning line 9 and the data line 8. In the pixel 3, a thin film transistor 10 for switching is provided. The thin film transistor 10 is one example of the “switching element” of the present application. The source (S) of the thin film transistor 10 is connected to the data line 8, and the gate (G) of the thin film transistor 10 is connected to the scanning line 9. The drain (D) of the thin film transistor 10 is connected to a pixel electrode 11. A counter electrode 13 is so provided as to be opposed to the pixel electrode 11 with the intermediary of a liquid crystal layer 12.

The drive IC 5 is so configured as to generate a VGL signal at the L level, an STV signal (start signal), a CK1 signal, and a CK2 signal as the substantially-inverted signal of the CK1 signal, and output these signals to the scanning line drive circuit 6. The CK1 signal is a pulse clock signal for forming the output signal of the scanning line drive circuit 6 and shifting the output signal. The CK2 signal is also a clock signal for shifting the output signal. The CK1 signal is one example of the “first clock signal” of the present application, and the CK2 signal is one example of the “second clock signal” of the present application. The signal at the H level (H-level signal) is a signal of the higher potential side and is e.g. a signal of +15 V. The signal at the L level (L-level signal) is a signal of the lower potential side and is e.g. a signal of −10 V. The CK2 signal, which is the substantially-inverted signal, is e.g. a signal whose phase is inverted from that of the CK1 signal and a signal substantially having an inversion relationship with respect to the CK1 signal as shown in FIG. 4 to be described later. However, the CK2 signal includes such a signal component that a period during which both the CK1 signal and the CK2 signal are at the L level exists. This period during which both signals are at the L level is equal to or shorter than about 10% of one cycle.

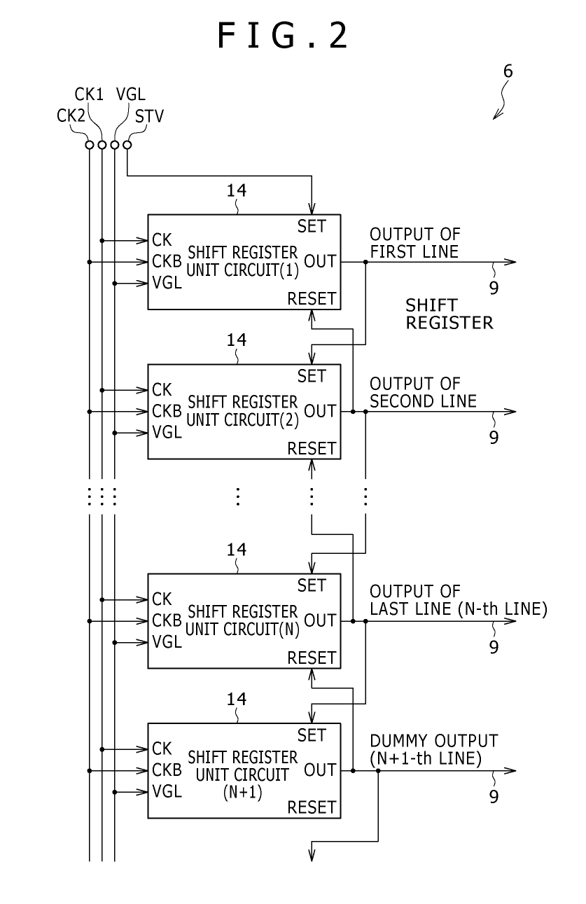

As shown in FIG. 2, the scanning line drive circuit 6 includes shift register unit circuits 14 of plural stages. The shift register unit circuit 14 has a function to output a signal from an OUT terminal and sequentially transfer the signal to the shift register unit circuit 14 of the next stage. The shift register unit circuit 14 outputs the CK1 signal or the CK2 signal from the OUT terminal, which is an output terminal of the scanning line drive circuit 6, to the scanning line 9. The plural shift register unit circuits 14 are connected to the first line, the second line, the N-th line, and the (N+1)-th line, respectively, of the scanning lines 9. The shift register unit circuit 14 connected to the scanning line 9 of the first line is diagrammatically represented as shift register unit circuit (1). The shift register unit circuit 14 connected to the scanning line 9 of the second line is represented as shift register unit circuit (2). The shift register unit circuit 14 connected to the scanning line 9 of the N-th line is represented as shift register unit circuit (N). The shift register unit circuit 14 connected to the scanning line 9 of the (N+1)-th line is represented as shift register unit circuit (N+1).

The first-stage shift register unit circuit 14 connected to the scanning line 9 of the first line from the scanning line drive circuit 6 includes a CK terminal to which the CK1 signal is input, a CKB terminal to which the CK2 signal is input, a VGL terminal to which the VGL signal at the L level is input, an SET terminal to which the STV signal is input, the OUT terminal for outputting a signal to the scanning line 9, and a RESET terminal to which a signal from the OUT terminal of the shift register unit circuit 14 of the next stage is input. The second-stage shift register unit circuit 14 connected to the scanning line 9 of the second line includes the CKB terminal to which the CK1 signal is input, the CK terminal to which the CK2 signal is input, the VGL terminal to which the VGL signal at the L level is input, the SET terminal to which a signal output from the OUT terminal of the shift register unit circuit 14 of the previous stage is input, the OUT terminal for outputting a signal to the scanning line 9, and the RESET terminal to which the signal from the OUT terminal of the shift register unit circuit 14 of the next stage is input. To the SET terminal of the shift register unit circuit 14 of the second stage or a subsequent stage, the signal output from the OUT terminal of the shift register unit circuit 14 of the previous stage is input. To the CK terminal and the CKB terminal of the shift register unit circuit 14 of the odd-numbered stage, the CK1 signal and the CK2 signal, respectively, are input. To the CK terminal and the CKB terminal of the shift register unit circuit 14 of the even-numbered stage, the CK2 signal and the CK1 signal, respectively, are input. The other configuration of the shift register unit circuit 14 of the second stage or a subsequent stage is the same as that of the first-stage shift register unit circuit 14. The dummy shift register unit circuit 14 is provided at the next stage of the shift register unit circuit 14 connected to the scanning line 9 of the last line.

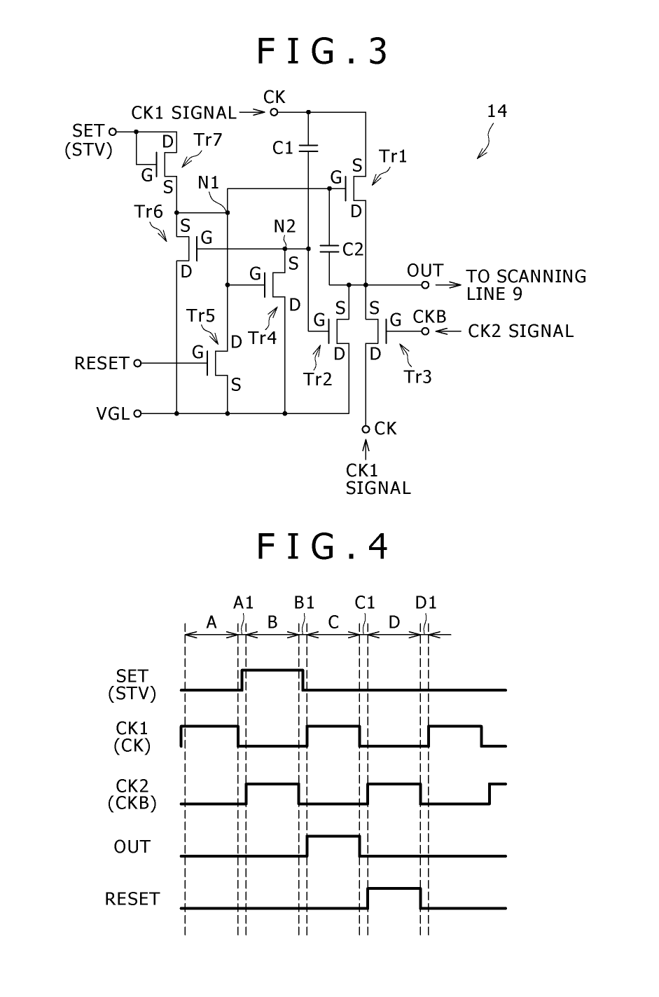

As the detailed configuration of the shift register unit circuit 14, as shown in FIG. 3, the shift register unit circuit 14 is composed of seven n-type transistors (transistor Tr1, transistor Tr2, transistor Tr3, transistor Tr4, transistor Tr5, transistor Tr6, and transistor Tr7) that have an active layer formed of amorphous silicon and have the same conductivity type, i.e. the n-type, and two capacitors (capacitor C1 and capacitor C2). The transistor Tr3 is one example of the “first transistor” of the present application. The transistor Tr1 is one example of the “second transistor” of the present application. The transistor Tr2 is one example of the “third transistor” of the present application.

The source (S) of the transistor Tr1 is connected to the CK terminal and the pulse CK1 signal (clock signal) is input thereto. Furthermore, the source (S) of the transistor Tr1 is connected to one electrode of the capacitor C1. The drain (D) of the transistor Tr1 is connected to the scanning line 9 (see FIG. 1) via the OUT terminal.

Furthermore, the drain (D) of the transistor Tr1 is connected to the source (S) of the transistor Tr2, the source (S) of the transistor Tr3, and one electrode of the capacitor C2. The gate (G) of the transistor Tr1 is connected to the gate (G) of the transistor Tr4, the drain (D) of the transistor Tr5, the source (S) of the transistor Tr6, the source (S) of the transistor Tr7, and the other electrode of the capacitor C2.

The drain (D) of the transistor Tr2 is connected to the drain (D) of the transistor Tr4, the source (S) of the transistor Tr5, the drain (D) of the transistor Tr6, and the VGL terminal. The gate (G) of the transistor Tr2 is connected to the source (S) of the transistor Tr4, the gate (G) of the transistor Tr6, and the other electrode of the capacitor C1.

In the first embodiment, the gate (G) of the transistor Tr3 is connected to the CKB terminal and the pulse CK2 signal is input thereto. The drain (D) of the transistor Tr3 is connected to the CK terminal and the pulse CK1 signal is input thereto. When the H-level signal is input to the gate (G) of the transistor Tr3, the L-level signal is input to the drain (D) of the transistor Tr3. When the L-level signal is input to the gate (G) of the transistor Tr3, the H-level signal is input to the drain (D) of the transistor Tr3.

In the first embodiment, when the CK2 signal at the H level is input to the gate (G) of the transistor Tr3 and the CK1 signal at the L level is input to the drain (D) of the transistor Tr3, the voltage of the gate of the transistor Tr3 becomes higher than the voltage of its channel. Thus, a charge is drawn toward the gate side of the transistor Tr3 and accumulated on the gate insulating film side. Next, when the CK2 signal at the L level is input to the gate (G) of the transistor Tr3 and the CK1 signal at the H level is input to the drain (D) of the transistor Tr3, the voltage of the channel of the transistor Tr3 becomes higher than the voltage of its gate. This causes the charge accumulated on the gate insulating film side of the transistor Tr3 to be moved from the gate insulating film side to the drain (D) side. As a result, a charge is less readily accumulated on the gate insulating film side of the transistor Tr3.

The gate (G) of the transistor Tr5 is connected to the RESET terminal and the output signal from the OUT terminal of the shift register unit circuit 14 of the next stage is input thereto. The drain (D) of the transistor Tr7 and the gate (G) of the transistor Tr7 are connected to the SET terminal. To the SET terminal of the shift register unit circuit 14 connected to the scanning line 9 of the first line, the STV signal (start signal) is input. To the SET terminal of the shift register unit circuit 14 connected to the scanning line 9 of the second line or a subsequent line, the output signal from the OUT terminal of the shift register unit circuit 14 of the previous stage is input.

With reference to FIG. 1 to FIG. 4, the operation of the above-described scanning line drive circuit 6 will be described below.

First, in the shift register unit circuit 14 (see FIG. 2) for the first line from the scanning line drive circuit 6, in a time A shown in FIG. 4, the L-level STV signal shown in FIG. 3 is input to the gate (G) of the transistor Tr7, and thus the transistor Tr7 is in the off-state. A signal is not input to the gates (G) of the transistors Tr1 and Tr4 connected to the source (S) of the transistor Tr7, and thus the transistors Tr1 and Tr4 are in the off-state. The CK1 signal at the H level is input to the gates (G) of the transistors Tr2 and Tr6 via the capacitor C1, and thus the transistors Tr2 and Tr6 are in the on-state. At this time, the VGL signal at the L level is input to the drains (D) of the transistors Tr2 and Tr6. This L-level VGL signal is output to the scanning line 9 (see FIG. 1) via the transistor Tr2 and the OUT terminal. The CK2 signal at the L level is input to the gate (G) of the transistor Tr3, and thus the transistor Tr3 is in the off-state. The RESET signal at the L level is input to the gate (G) of the transistor Tr5, and thus the transistor Tr5 is in the off-state.

Near the end of the time A shown in FIG. 4, the CK1 signal becomes the L-level state from the H-level state. Thus, in a time A1, both the CK1 signal and the CK2 signal are in the L-level state. That is, in the time A1, the L-level signal is input to both the gate (G) and drain (D) of the transistor Tr3. Immediately after the passage of the time A1, the CK2 signal becomes the H-level state from the L-level state.

Next, in the shift register unit circuit 14 (see FIG. 2) for the first line from the scanning line drive circuit 6, in a time B shown in FIG. 4, the H-level STV signal shown in FIG. 3 is input to the gate (G) of the transistor Tr7, and thus the transistor Tr7 is in the on-state. Thereby, the H-level signal is input via a node N1 to the gate (G) of the transistor Tr1, the gate (G) of the transistor Tr4, the drain (D) of the transistor Tr5, the source (S) of the transistor Tr6, and the other electrode of the capacitor C2. As a result, the transistor Tr1 and the transistor Tr4 are in the on-state. Furthermore, a node N2 is at the L-level potential. The other electrode of the capacitor C2 becomes the H level and starts charging. Furthermore, in the first embodiment, the CK2 signal at the H level is input to the gate (G) of the transistor Tr3, and thus the transistor Tr3 is in the on-state. In addition, the CK1 signal at the L level is input to the drain (D) of the transistor Tr3, so that the L-level CK1 signal is output to the scanning line 9 via the transistor Tr3 and the OUT terminal. The VGL signal at the L level is input to the gate (G) of the transistor Tr2 and the gate (G) of the transistor Tr6 via the transistor Tr4 in the on-state. Thus, the transistor Tr2 and the transistor Tr6 are in the off-state. The RESET signal at the L level is input to the transistor Tr5, and therefore the transistor Tr5 remains the off-state.

Near the end of the time B shown in FIG. 4, the CK2 signal becomes the L-level state from the H-level state. Thus, in a time B1, both the CK1 signal and the CK2 signal are in the L-level state. That is, in the time B1, the L-level signal is input to both the gate (G) and drain (D) of the transistor Tr3. Immediately after the passage of the time B1, the CK1 signal becomes the H-level state from the L-level state, and the H-level CK1 signal is input to the drain (D) of the transistor Tr3. At this time, the L-level CK2 signal is input to the gate (G) of the transistor Tr3, and thus the transistor Tr3 is in the off-state. Therefore, the H-level CK1 signal input to the drain (D) of the transistor Tr3 is not output to the OUT terminal via the transistor Tr3.

Next, in the shift register unit circuit 14 (see FIG. 2) for the first line from the scanning line drive circuit 6, in a time C shown in FIG. 4, the L-level STV signal shown in FIG. 3 is input to the gate (G) of the transistor Tr7, and thus the transistor Tr7 is in the off-state. At this time, the H-level signal is discharged from the capacitor C2 charged in the above-described time B, and the H-level signal is input to the gate (G) of the transistor Tr1 and the gate (G) of the transistor Tr4. Thus, the transistor Tr1 and the transistor Tr4 remain the on-state. The CK1 signal at the H level is output from the OUT terminal to the scanning line 9 via the transistor Tr1. Thereby, the output signal drives the thin film transistor 10 provided in the pixel 3 of the display unit 4. Furthermore, the signal output to the OUT terminal is input to the SET terminal of the shift register unit circuit 14 of the next stage. The VGL signal at the L level is input to the gate (G) of the transistor Tr2 and the gate (G) of the transistor Tr6 via the transistor Tr4 and the node N2, and thus the transistor Tr2 and the transistor Tr6 remain the off-state.

Near the end of the time C shown in FIG. 4, the CK1 signal becomes the L-level state from the H-level state. Thus, in a time C1, both the CK1 signal and the CK2 signal are in the L-level state. That is, in the time C1, the L-level signal is input to both the gate (G) and drain (D) of the transistor Tr3. Immediately after the passage of the time C1, the CK2 signal becomes the H-level state from the L-level state, and the L-level CK1 signal is input to the drain (D) of the transistor Tr3. At this time, the H-level CK2 signal is input to the gate (G) of the transistor Tr3, and thus the transistor Tr3 is in the on-state. Therefore, the L-level CK1 signal input to the drain (D) of the transistor Tr3 is output to the OUT terminal via the transistor Tr3.

Next, in the shift register unit circuit 14 (see FIG. 2) for the first line from the scanning line drive circuit 6, in a time D shown in FIG. 4, the L-level STV signal shown in FIG. 3 is input to the gate (G) of the transistor Tr7, and thus the transistor Tr7 remains the off-state. The CK1 signal at the L level is input to the source (S) of the transistor Tr1. Furthermore, in the first embodiment, the CK2 signal at the H level is input to the gate (G) of the transistor Tr3, and thus the transistor Tr3 is in the on-state. Therefore, the L-level signal is output to the scanning line 9 via the transistor Tr3 and the OUT terminal.

Near the end of the time D shown in FIG. 4, the CK2 signal becomes the L-level state from the H-level state. Thus, in a time D1, both the CK1 signal and the CK2 signal are in the L-level state. That is, in the time D1, the L-level signal is input to both the gate (G) and drain (D) of the transistor Tr3. Immediately after the passage of the time D1, the CK1 signal becomes the H-level state from the L-level state, and the H-level CK1 signal is input to the drain (D) of the transistor Tr3. At this time, the L-level CK2 signal is input to the gate (G) of the transistor Tr3, and thus the transistor Tr3 is in the off-state. Therefore, the H-level signal input to the drain (D) of the transistor Tr3 is not output to the OUT terminal via the transistor Tr3.

The H-level RESET signal output from the shift register unit circuit 14 for the second line (next stage) is input to the gate (G) of the transistor Tr5, and thus the transistor Tr5 is in the on-state. The VGL signal at the L level is input via the transistor Tr5 to the gate (G) of the transistor Tr1, the gate (G) of the transistor Tr4, the source (S) of the transistor Tr6, and the source (S) of the transistor Tr7. Therefore, the transistor Tr1 and the transistor Tr4 are in the off-state. A signal is not input to the gate (G) of the transistor Tr2 and the gate (G) of the transistor Tr6, and thus these transistors are in the floating state. The procedure of the scanning operation for the second line and the subsequent lines is the same as that of the above-described scanning operation for the first line.

In the first embodiment, as described above, when the CK2 signal at the H level is input to the gate (G) of the transistor Tr3, the CK1 signal at the L level is input to the drain (D) of the transistor Tr3. In addition, when the L-level signal is input to the gate (G) of the transistor Tr3, the H-level signal is input to the drain (D) of the transistor Tr3. Due to this feature, when the H-level signal is input to the gate (G) of the transistor Tr3 and the L-level signal is input to the drain (D) of the transistor Tr3, the voltage of the gate (G) of the transistor Tr3 becomes higher than the voltage of its channel (voltage between source (S) and drain (D)). Thus, a charge is drawn toward the gate (G) side of the transistor Tr3 and accumulated on the gate insulating film side. On the other hand, when the L-level signal is input to the gate (G) of the transistor Tr3 and the H-level signal is input to the drain (D) of the transistor Tr3, the voltage of the channel of the transistor Tr3 (voltage between source (S) and drain (D)) becomes higher than the voltage of its gate (G). Thus, the charge accumulated on the gate insulating film side of the transistor Tr3 is moved from the gate insulating film side to the source (S) or drain (D) side. This allows a charge to be less readily accumulated on the gate insulating film side of the transistor Tr3 and thus can suppress the shift of the threshold voltage of the transistor Tr3 attributed to the accumulation of a charge on the gate insulating film side. As a result, the deterioration of the transistor Tr3 is suppressed, which can extend the life of the scanning line drive circuit 6.

Furthermore, in the first embodiment, as described above, one of the CK1 signal and the CK2 signal is switched from the L level to the H level after the passage of the period during which both of the CK1 signal input to the drain (D) of the transistor Tr3 and the CK2 signal input to the gate (G) of the transistor Tr3 are at the L level. Due to this feature, one of the CK1 signal and the CK2 signal becomes the H level from the L level after the transistor Tr3 is surely set to the off-state. This can suppress outputting of the H-level signal before the setting of the transistor Tr3 to the off-state.

In addition, in the first embodiment, as described above, the drain (D) of the transistor Tr1 is connected to the source (S) of the transistor Tr3 and forms the output terminal (OUT) of the shift register unit circuit 14, and the output terminal (OUT) of the shift register unit circuit 14 is connected to the input terminal of the next stage of the shift register unit circuit 14. This allows a charge to be less readily accumulated on the gate insulating film side of the transistors Tr1 and Tr3 and thus can suppress the shift of the threshold voltage of the transistors Tr1 and Tr3 attributed to the accumulation of a charge on the gate insulating film side. Thereby, the signal can be surely output to the scanning line 9.

Moreover, in the first embodiment, as described above, particularly if the transistors Tr1 to Tr7 are n-conductivity-type transistors having an active layer formed of amorphous silicon, which is susceptible to performance deterioration, the life of the shift register unit circuit 14 can be extended because the performance deterioration can be suppressed.

### Second Embodiment

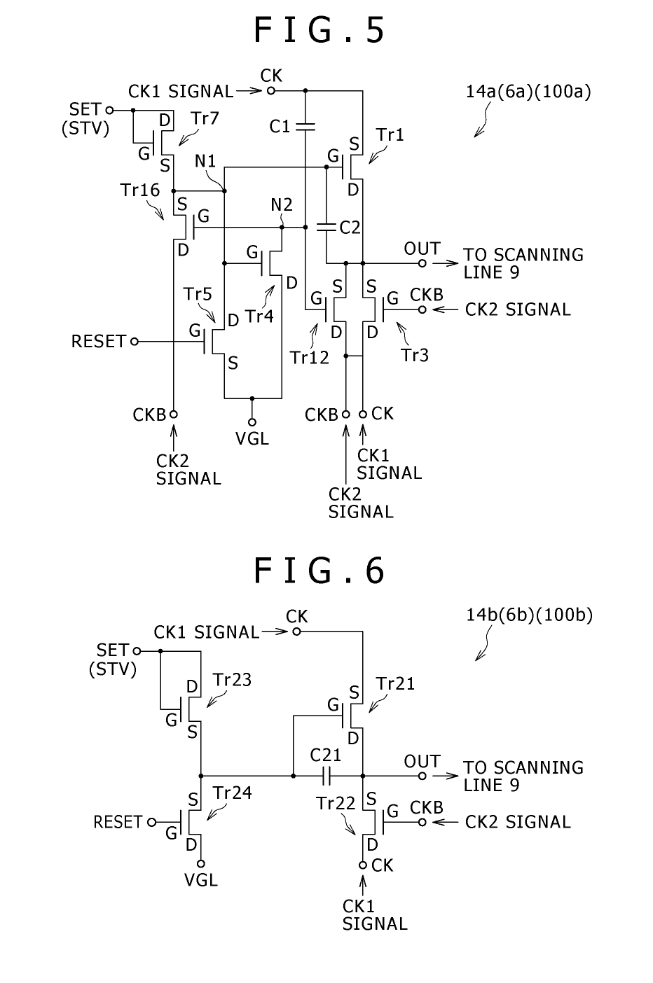

With reference to FIG. 5, a second embodiment will be described below. In a liquid crystal display device 100a provided with a scanning line drive circuit 6a according to this second embodiment, the pulse CK2 signal (clock signal) is input also to the drain (D) of a transistor Tr12 in addition to the transistor Tr3, differently from the above-described first embodiment, in which the pulse CK2 signal (clock signal) is input to only the gate of the transistor Tr3.

In the liquid crystal display device 100a provided with the scanning line drive circuit 6a according to this second embodiment, as shown in FIG. 5, a shift register unit circuit 14a is composed of seven n-type transistors (transistor Tr1, transistor Tr12, transistor Tr3, transistor Tr4, transistor Tr5, transistor Tr16, and transistor Tr7) that have an active layer formed of amorphous silicon and have the same conductivity type, i.e. the n-type, and two capacitors (capacitor C1 and capacitor C2). The liquid crystal display device 100a is one example of the “electro-optical device” of the present application. The transistor Tr12 is one example of the “third transistor” of the present application. The capacitor C1 is one example of the “capacitor” of the present application.

The drain (D) of the transistor Tr12 is connected to the CKB terminal and the pulse CK2 signal is input thereto. The drain (D) of the transistor Tr16 is connected to the CKB terminal and the pulse CK2 signal is input thereto. The CK2 signal input to the drains (D) of the transistors Tr12 and Tr16 is the same signal as the CK2 signal input to the gate (G) of the transistor Tr3. To the gates (G) of the transistors Tr12 and Tr16, the CK1 signal input to the drain (D) of the transistor Tr3 is input via the capacitor C1. A signal smaller than the signal input to the drain (D) of the transistor Tr3 is input to the gates of the transistors Tr12 and Tr16 because a charge is divided among the capacitance of the capacitor C1 and the gates (G) of the transistors Tr12 and Tr16 when the CK1 signal input to the gates (G) of the transistors Tr12 and Tr16 becomes the H level from the L level.

Furthermore, in the second embodiment, when the CK1 signal at the H level is input to the gates (G) of the transistors Tr12 and Tr16, the CK2 signal at the L level is input to the drains (D) of the transistors Tr12 and Tr16. In addition, when the CK1 signal at the L level is input to the gates (G) of the transistors Tr12 and Tr16, the CK2 signal at the H level is input to the drains (D) of the transistors Tr12 and Tr16.

When the H-level CK1 signal is input to the gates (G) of the transistors Tr12 and Tr16 and the L-level CK2 signal is input to the drains (D) of the transistors Tr12 and Tr16, the voltage of the gates (G) of the transistors Tr12 and Tr16 becomes higher than the voltage of their channels. Thus, a charge is drawn toward the gate side of the transistors Tr12 and Tr16 and accumulated on the gate insulating film side. Next, when the L-level CK1 signal is input to the gates (G) of the transistors Tr12 and Tr16 and the H-level CK2 signal is input to the drains (D) of the transistors Tr12 and Tr16, the voltage of the channels of the transistors Tr12 and Tr16 becomes higher than the voltage of their gates. Thereby, the charge accumulated on the gate insulating film side of the transistors Tr12 and Tr16 is moved from the gate insulating film side to the drain (D) side, differently from the case in which the H-level CK1 signal is input to the gates (G) of the transistors Tr12 and Tr16 and the L-level CK2 signal is input to the drains (D) of the transistors Tr12 and Tr16. As a result, a charge is less readily accumulated on the gate insulating film side of the transistors Tr12 and Tr16. The other configuration and operation of the second embodiment are the same as those of the above-described first embodiment.

In the second embodiment, as described above, in each of the shift register unit circuits 14a of plural stages, the L-level signal is input to the drains (D) of the transistors Tr12 and Tr16 when the H-level signal is input to the gates (G) of the transistors Tr12 and Tr16 via the capacitor C1. In addition, the H-level signal is input to the drains (D) of the transistors Tr12 and Tr16 when the L-level signal is input to the gates (G) of the transistors Tr12 and Tr16 via the capacitor C1. This allows a charge to be less readily accumulated on the gate insulating film side of the transistor Tr12 in addition to the gate insulating film side of the transistors Tr1 and Tr3, and thus can suppress the shift of the threshold voltage of the transistor Tr12 attributed to the accumulation of a charge on the gate insulating film side. Consequently, the shift of the threshold voltage of the transistor Tr1, the transistor Tr3, and the transistor Tr12 can be suppressed.

Furthermore, in the second embodiment, as described above, the same signal as the signal input to the drain (D) of the transistor Tr3 is input to the gate (G) of the transistor Tr12 via the capacitor C1. Thus, the signal for suppressing the shift of the threshold voltage of the transistor Tr12 does not need to be additionally prepared, which can suppress increase in the degree of complexity of the circuit configuration.

The other advantageous effects of the second embodiment are the same as those of the above-described first embodiment.

### Third Embodiment

With reference to FIG. 6, a third embodiment will be described below. A liquid crystal display device 100b provided with a scanning line drive circuit 6b according to the third embodiment includes a shift register unit circuit configured by four transistors, differently from the above-described first embodiment, in which the shift register unit circuit is configured by seven transistors.

In the liquid crystal display device 100b provided with the scanning line drive circuit 6b according to the third embodiment, as shown in FIG. 6, a shift register unit circuit 14b is composed of four n-type transistors (transistor Tr21, transistor Tr22, transistor Tr23, and transistor Tr24) that have an active layer formed of amorphous silicon and have the same conductivity type, i.e. the n-type, and one capacitor C21. The liquid crystal display device 100b is one example of the “electro-optical device” of the present application. The transistor Tr22 is one example of the “first transistor” of the present application. The transistor Tr21 is one example of the “second transistor” of the present application.

The source (S) of the transistor Tr21 is connected to the CK terminal and the pulse CK1 signal is input thereto. The drain (D) of the transistor Tr21 is connected to one electrode of the capacitor C21, the OUT terminal, and the source (S) of the transistor Tr22. The gate (G) of the transistor Tr21 is connected to the other electrode of the capacitor C21, the source (S) of the transistor Tr23, and the source (S) of the transistor Tr24.

Furthermore, in the third embodiment, the gate (G) of the transistor Tr22 is connected to the CKB terminal and the pulse CK2 signal is input thereto. The drain (D) of the transistor Tr22 is connected to the CK terminal and the pulse CK1 signal is input thereto. The CK1 signal and the CK2 signal are pulse signals substantially inverted from each other.

When the CK2 signal at the H level is input to the gate (G) of the transistor Tr22 and the CK1 signal at the L level is input to the drain (D) of the transistor Tr22, the voltage of the gate (G) of the transistor Tr22 becomes higher than the voltage of its channel. Thus, a charge is drawn toward the gate side of the transistor Tr22 and accumulated on the gate insulating film side. Next, when the CK2 signal at the L level is input to the gate (G) of the transistor Tr22 and the CK1 signal at the H level is input to the drain (D) of the transistor Tr22, the voltage of the channel of the transistor Tr22 becomes higher than the voltage of its gate. This causes the charge accumulated on the gate insulating film side of the transistor Tr22 to be moved from the gate insulating film side to the drain (D) side. As a result, a charge is less readily accumulated on the gate insulating film side of the transistor Tr22.

The drain (D) and gate (G) of the transistor Tr23 are connected to the SET terminal (STV terminal) and the SET signal (STV signal) is input. The drain (D) of the transistor Tr24 is connected to the VGL terminal, to which the L-level signal is input. The gate (G) of the transistor Tr24 is connected to the RESET terminal and the output signal from the OUT terminal of the shift register unit circuit 14b of the next stage is input. The other configuration and operation of the third embodiment are the same as those of the above-described first embodiment.

### Application Examples

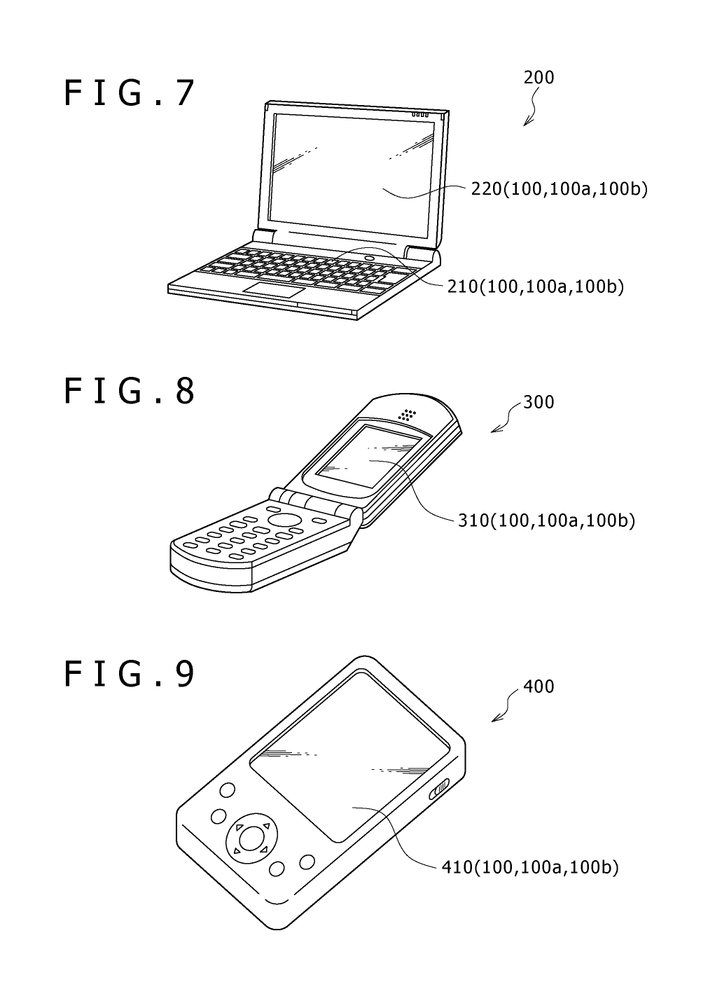

FIG. 7 to FIG. 9 are diagrams for explaining a first example to a third example of electronic apparatus employing the liquid crystal display devices 100, 100a, and 100b provided with the scanning line drive circuits 6, 6a, and 6b, respectively, according to the above-described embodiments of the present application. With reference to FIG. 7 to FIG. 9, the electronic apparatus employing the liquid crystal display devices 100, 100a, and 100b according to the embodiments of the present application will be described below.

As shown in FIG. 7 to FIG. 9, the liquid crystal display devices 100, 100a, and 100b provided with the scanning line drive circuits 6, 6a, and 6b according to the embodiments of the present application can be used for a personal computer (PC) 200 as the first example, a cellular phone 300 as the second example, an information portable terminal (personal digital assistant (PDA)) 400 as the third example, etc.

In the PC 200 of the first example of FIG. 7, the liquid crystal display devices 100, 100a, and 100b provided with the scanning line drive circuits 6, 6a, and 6b according to the embodiments of the present application can be used for an input unit 210 such as a keyboard, a display screen 220, and so forth. In the cellular phone 300 of the second example of FIG. 8, the liquid crystal display devices 100, 100a, and 100b provided with the scanning line drive circuits 6, 6a, and 6b according to the embodiments of the present application can be used for a display screen 310. In the information portable terminal 400 of the third example of FIG. 9, the liquid crystal display devices 100, 100a, and 100b provided with the scanning line drive circuits 6, 6a, and 6b according to the embodiments of the present application can be used for a display screen 410.

The embodiments disclosed in the present specification should be considered as examples and being not limiting entities in all points. The scope of the present application is indicated by not the above description of the embodiments but the scope of the claims, and encompasses all changes in the sense of being equivalent to the scope of the claims and within the scope of the claims.

For example, the above-described first to third embodiments relate to application to the liquid crystal display device. However, the present application is not limited to the liquid crystal display device. For example, the present application can be applied to a display device other than the liquid crystal display device.

Furthermore, in the above-described first to third embodiments, the shift register unit circuit is configured by seven transistors and by four transistors as examples. However, the present application is not limited thereto. In the present application, the shift register unit circuit may be configured by transistors whose number is other than seven and four.

In addition, in the above-described first to third embodiments, the H-level signal and the L-level signal are alternately input to the gate (G) and drain (D) of the transistor in a continuous manner as examples. However, the present application is not limited thereto. For example, the H-level signal and the L-level signal may be input to the gate (G) and drain (D) of the transistor one time for each signal.

Moreover, in the above-described first to third embodiments, the H-level signal and the L-level signal are input to the gate (G) and drain (D) of the transistor as examples. However, the present application is not limited thereto. For example, the H-level signal and the L-level signal may be input to the gate (G) and source (S) of the transistor.

Furthermore, in the above-described first to third embodiments, scanning line drive circuits to which transistors having an active layer formed of amorphous silicon are applied are shown as one example of the scanning line drive circuit of the present application. However, the present application is not limited thereto. For example, transistors having an active layer formed of low-temperature poly-silicon (LTPS) or high-temperature poly-silicon (HTPS) may be applied to the scanning line drive circuit.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

1. A shift register comprising:
shift register unit circuits of a plurality of stages, wherein
each of the shift register unit circuits of the plurality of stages includes a first transistor having a source and a drain to one of which a first clock signal is input and a gate to which a second clock signal obtained by substantially inverting the first clock signal is input, and
when the second clock signal at one of an H level and an L level is input to the gate of the first transistor, the first clock signal at the other of the H level and the L level is input to one of the source and the drain of the first transistor.

2. The shift register according to claim 1, wherein
one of the first clock signal and the second clock signal becomes the H level from the L level after passage of a period during which both of the first clock signal input to one of the source and the drain of the first transistor and the second clock signal input to the gate of the first transistor are at the L level.

3. The shift register according to claim 1, wherein
each of the shift register unit circuits of the plurality of stages includes a second transistor having a source and a drain to one of which the first clock signal is input,
the other of the source and the drain of the second transistor is connected to the other of the source and the drain of the first transistor and forms an output terminal of the shift register unit circuit, and
the output terminal of the shift register unit circuit is connected to an input terminal of a next stage of the shift register unit circuit.

4. The shift register according to claim 3, wherein
each of the shift register unit circuits of the plurality of stages includes a capacitor having one electrode to which the same signal as a signal input to one of the source and the drain of the first transistor is input, and a third transistor having a gate connected to the other electrode of the capacitor, and
a signal at the L level is input to one of a source and a drain of the third transistor when a signal at the H level is input to the gate of the third transistor via the capacitor, and a signal at the H level is input to one of the source and the drain of the third transistor when a signal at the L level is input to the gate of the third transistor via the capacitor.

5. The shift register according to claim 4, wherein
the same signal as a signal input to the gate of the first transistor is input to one of the source and the drain of the third transistor, and
the same signal as the signal input to one of the source and the drain of the first transistor is input to the gate of the third transistor via the capacitor.

6. The shift register according to claim 3, wherein
the first and second transistors each have an active layer formed of amorphous silicon.

7. The shift register according to claim 3, wherein
the first and second transistors are transistors of the same conductivity type.

8. A scanning line drive circuit that is provided together with a plurality of scanning lines, a plurality of data lines, and switching elements provided corresponding to intersections of the scanning lines and the data lines, and is connected to the scanning lines, the scanning line drive circuit comprising:
the shift register including:
shift register unit circuits of a plurality of stages,
each of the shift register unit circuits of the plurality of stages including a first transistor having a source and a drain to one of which a first clock signal is input and a gate to which a second clock signal obtained by substantially inverting the first clock signal is input, and
when the second clock signal at one of an H level and an L level is input to the gate of the first transistor, the first clock signal at the other of the H level and the L level being input to one of the source and the drain of the first transistor,
wherein the output terminal of the shift register unit circuit is connected to the scanning line.

9. An electro-optical device comprising:
the scanning line drive circuit that is provided together with a plurality of scanning lines, a plurality of data lines, and switching elements provided corresponding to intersections of the scanning lines and the data lines, and is connected to the scanning lines, the scanning line drive circuit having the shift register including
shift register unit circuits of a plurality of stages,
each of the shift register unit circuits of the plurality of stages including a first transistor having a source and a drain to one of which a first clock signal is input and a gate to which a second clock signal obtained by substantially inverting the first clock signal is input, and
when the second clock signal at one of an H level and an L level is input to the gate of the first transistor, the first clock signal at the other of the H level and the L level being input to one of the source and the drain of the first transistor,
wherein the output terminal of the shift register unit circuit is connected to the scanning line.

10. Electronic apparatus comprising:
the electro-optical device including the scanning line drive circuit that is provided together with a plurality of scanning lines, a plurality of data lines, and switching elements provided corresponding to intersections of the scanning lines and the data lines, and is connected to the scanning lines, the scanning line drive circuit having the shift register including
shift register unit circuits of a plurality of stages,
each of the shift register unit circuits of the plurality of stages including a first transistor having a source and a drain to one of which a first clock signal is input and a gate to which a second clock signal obtained by substantially inverting the first clock signal is input, and
when the second clock signal at one of an H level and an L level is input to the gate of the first transistor, the first clock signal at the other of the H level and the L level being input to one of the source and the drain of the first transistor,
wherein the output terminal of the shift register unit circuit is connected to the scanning line.
